(19) United States
(12) Patent Application Publication
(10) Pub. No.: US 2025/0311246 A1
(43) Pub. Date: Oct. 2, 2025

(54) VERTICALLY STACKED CAPACITORS AND METHOD OF FORMING THE SAME

(71) Applicant: Tokyo Electron Limited, Tokyo (JP)

(72) Inventor: Alec DORFNER, Albany, NY (US)

(73) Assignee: Tokyo Electron Limited, Tokyo (JP)

(21) Appl. No.: 18/619,016

(22) Filed: Mar. 27, 2024

(51) Int. Cl. H10D 1/00; H10D 1/68

(52) U.S. Cl. CPC H10D 1/042; H10D 1/716

(57) ABSTRACT

A semiconductor device and method of manufacturing the semiconductor device are provided. The semiconductor device includes a substrate and a stack of alternating first layers and second layers on a working surface of the substrate. The semiconductor device includes a capacitor array including a plurality of capacitors. A common electrode of the capacitor array is disposed through the stack of alternating first layers and second layers on the working surface of the substrate. Each of the plurality of capacitors is sandwiched between two adjacent first layers and includes a first electrode extending along a direction parallel to the working surface of the substrate and from the common electrode to one of the second layers between the two adjacent first layers, a dielectric layer disposed over the first electrode, and a second electrode disposed over the dielectric layer.

### TECHNICAL FIELD

This disclosure relates to three-dimensional semiconductor device, and particularly to a vertical three-dimensional capacitor array and a method of manufacturing same.

### BACKGROUND

As dynamic random access memory (DRAM) capacitors are shrinking to a smaller critical dimension (CD) and tighter pitch to reduce manufacturing cost and increase storage density, scaling a planar capacitor in the memory device faces various challenges due to process technology limitations and reliability issues. A three-dimensional (3D) vertical capacitor can address the density and performance limitation in the memory device.

### SUMMARY

This disclosure provides a semiconductor device. The semiconductor device includes a substrate and a stack of alternating first layers and second layers on a working surface of the substrate. The semiconductor device includes a capacitor array including a plurality of capacitors. A common electrode of the capacitor array is disposed through the stack of alternating first layers and second layers on the working surface of the substrate. Each of the plurality of capacitors is sandwiched between two adjacent first layers and includes a first electrode extending along a direction parallel to the working surface of the substrate and from the common electrode to one of the second layers between the two adjacent first layers, a dielectric layer disposed over the first electrode, and a second electrode disposed over the dielectric layer.

Aspects of the disclosure further provide a method of manufacturing a semiconductor device. The method includes forming a stack of alternating first layers and second layers on a working surface of a substrate of the semiconductor device. The method further includes forming a capacitor array including a plurality of capacitors. A common electrode of the capacitor array is disposed through the stack of alternating first layers and second layers on the working surface of the substrate. Each of the plurality of capacitors is sandwiched between two adjacent first layers and comprises a first electrode extending along a direction parallel to the working surface of the substrate and from the common electrode to one of the second layers between the two adjacent first layers, a dielectric layer disposed over the first electrode, and a second electrode disposed over the dielectric layer.

### BRIEF DESCRIPTION OF DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A and 1B show a cross-section and a zoomed-in cross-section of a semiconductor device including a capacitor array, respectively, according to an embodiment of the disclosure.

FIGS. 2A-2C illustrate a series of processing steps of manufacturing the semiconductor device according to an embodiment of the disclosure.

FIG. 3 shows a flowchart illustrating a semiconductor process of manufacturing a semiconductor device according to an embodiment of the disclosure.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, the term “horizontal/horizontally/lateral/laterally” means nominally parallel to a lateral surface of a substrate, and the term “vertical” or “vertically” means nominally perpendicular to the lateral surface of a substrate.

A cylindrical shaped capacitor structure has been widely used to increase a surface area of a capacitor in a dynamic random-access memory (DRAM) device. However, as a critical dimension (CD) of the DRAM device decreases, a height of the cylindrical shaped capacitor structure needs to be increased in order to maintain an adequate surface area and capacitance for the DRAM capacitor, leading to an exponentially increased aspect ratio (AR) for the cylindrical shaped capacitor structure. For example, an AR of a cylindrical shaped DRAM capacitor has reached 100:1. Thus, two-dimensional (2D) scaling is reaching its limit for the DRAM capacitors.

In this disclosure, structures and manufacturing methods for vertical capacitors are presented. The vertical capacitors can allow a vertical scaling (i.e., 3D scaling) and thus a higher capacitor density. By using the vertical capacitors instead of the cylindrical shaped capacitors, an overall memory density of a memory device can be improved.

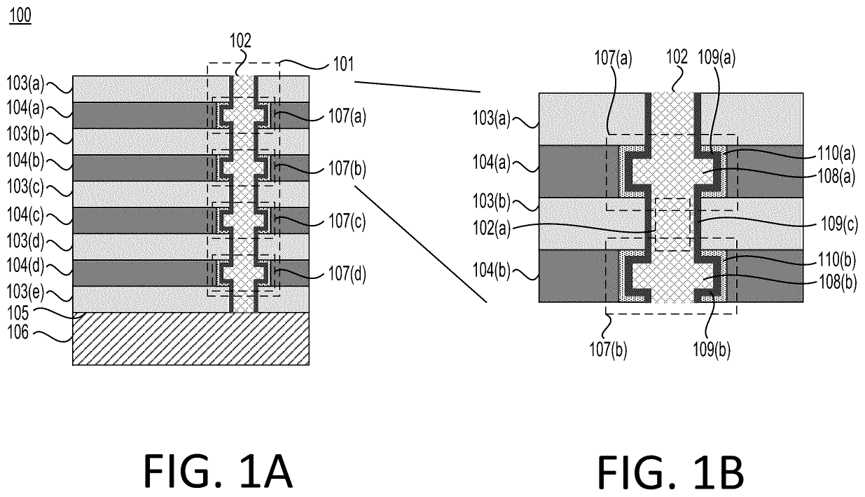

FIGS. 1A and 1B show a cross-section and a zoomed-in cross-section of a semiconductor device 100 including a capacitor array 101, respectively, according to an embodiment of the disclosure.

As shown in FIG. 1A, the capacitor array 101 includes a common electrode 102 that is disposed through a stack of alternating first layers 103 and second layers 104. The stack of alternating first layers 103 and second layers 104 is formed on a working surface 105 of a substrate 106 of the semiconductor 100. The capacitor array 101 includes a plurality of vertical capacitors 107. Each of the plurality of capacitors 107 is sandwiched between two adjacent first layers and includes a first electrode 108, a dielectric layer 109, and a second electrode 110. The first electrode 108 extends along a direction parallel to the working surface 105 of the substrate 106 and from the common electrode 102 to one of the second layers 104 between the two adjacent first layers. The dielectric layer 109 is disposed over the first electrode 108. The second electrode 110 is disposed over the dielectric layer 109.

For example, as shown in FIG. 1B, the vertical capacitor 107(a) of the capacitor array 101 is sandwiched between two adjacent first layers 103(a) and 103(b) and includes the first electrode 108(a), the dielectric layer 109(a), and the second electrode 110(a). The first electrode 108(a) extends along the direction parallel to the working surface 105 of the substrate 106 and from the common electrode 102 to the second layer 104(a) between the two adjacent first layers 103(a) and 103(b). The dielectric layer 109(a) is disposed over the first electrode 108(a). The second electrode 110(a) is disposed over the dielectric layer 109(a).

In the capacitor array 101, the dielectric layers 109 of two adjacent capacitors 107 are connected to each other through a dielectric layer surrounding a portion of the common electrode 102. The portion of the common electrode 102 is between two adjacent second layers 104. The dielectric layer surrounding the portion of the common electrode 102 is between the portion of the common electrode 102 and one of the first layers 103.

For example, still referring to FIG. 1B, the dielectric layers 109(a) and 109(b) of two adjacent capacitors 107(a) and 107(b) are connected to each other through a dielectric layer 109(c) surrounding a portion 102(a) of the common electrode 102. The portion 102(a) of the common electrode 102 is between the adjacent second layers 104(a) and 104(b). The dielectric layer 109(c) surrounding the portion 102(a) of the common electrode 102 is between the portion 102(a) of the common electrode 102 and the first layer 103(b). The first layer 103(b) is between the adjacent second layers 104(a) and 104(b).

In the capacitor array 101, the first electrode 108 of each vertical capacitor 107 can have first and second surfaces parallel to the working surface 105 of the substrate 106 and a third surface perpendicular to the working surface 105 of the substrate 106. For example, as shown in FIG. 1B, top and bottom surfaces of the first electrode 108(a) of the capacitor 107(a) can be parallel to the working surface 105 of the substrate 106, and a side surface of the first electrode 108(a) of the capacitor 107(a) can be perpendicular to the working surface 105 of the substrate 106.

The dielectric layer 109 of each vertical capacitor 107 can have three portions. First and second portions of the dielectric layer 109 respectively can be disposed over the first and second surfaces of the first electrode 108 of the respective capacitor 107, and a third portion of the dielectric layer 109 can be disposed over the third surface of the first electrode 108 of the respective capacitor 107. For example, as shown in FIG. 1B, a first portion (e.g., top portion) and a second portion (e.g., bottom portion) of the dielectric layer 109(a) are disposed over the top and bottom surfaces of the first electrode 108(a), respectively. A third portion (e.g., side portion) of the dielectric layer 109(a) is disposed over the side surface of the first electrode 108(a).

The second electrode 110 of each vertical capacitor 107 can have three portions. A first portion of the second electrode 110 can be disposed between the first portion of the dielectric layer 109 of the respective capacitor and one of the two adjacent first layers 104 immediately above the one of the second layers 103. A second portion of the second electrode 110 can be disposed between the second portion of the dielectric layer 109 of the respective capacitor and the other of the two adjacent first layers 104 immediately below the one of the second layers 103. A third portion of the second electrode 110 can be disposed between the third portion of the dielectric layer 109 of the respective capacitor and the one of the second layers 104.

For example, as shown in FIG. 1B, the second electrode 110(a) of the capacitor 107(a) can have three portions. A first portion (e.g., top portion) of the second electrode 110(a) is disposed over the top portion of the dielectric layer 109(a) and between the top portion of the dielectric layer 109(a) and the first layer 103(a) which is immediately above the second layer 104(a). A second portion (e.g., bottom portion) of the second electrode 110(a) is disposed over the bottom portion of the dielectric layer 109(a) and between the bottom portion of the dielectric layer 109(a) and the first layer 103(b) which is immediately below the second layer 104(a). A third portion (e.g., side portion) of the second electrode 110(a) is disposed over the side portion of the dielectric layer 109(a) and between the side portion of the dielectric layer 109(a) and the second layer 104(a).

In an embodiment, the first layers 103 can be insulating layers. For example, a material of the first layers 103 can be silicon oxide.

In an embodiment, the second layers 104 can be conducting layers or sacrificial layers. In an example, a material of the second layers 104 can be polysilicon if the second layers 104 are conducting layers. In an example, a material of the second layers 104 can be silicon nitride or silicon carbide if the second layers 104 are sacrificial layers.

In an embodiment, the first electrodes 108 of the plurality of capacitors 107 and the common electrode 102 of the capacitor array 101 can be formed of a same material. For example, a material of the first electrodes 108 and the common electrode 102 can be polysilicon or silicon germanium (SiGe).

In an embodiment, a material of the dielectric layer 109 can be a high-K (high dielectric constant) material such as metal oxide (e.g., ZrO₂ or Al₂O₃).

In an embodiment, a material of the second electrodes 110 can include any suitable conductive material such as Al, Cu, W, Ti, TiN, Si, or SiGe, or combinations thereof.

In an embodiment, the substrate 106 of the semiconductor device 100 can be a bulk silicon substrate. Alternatively, the substrate 106 can include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Alternatively, the substrate 106 can be a silicon-on-insulator (SOI) substrate.

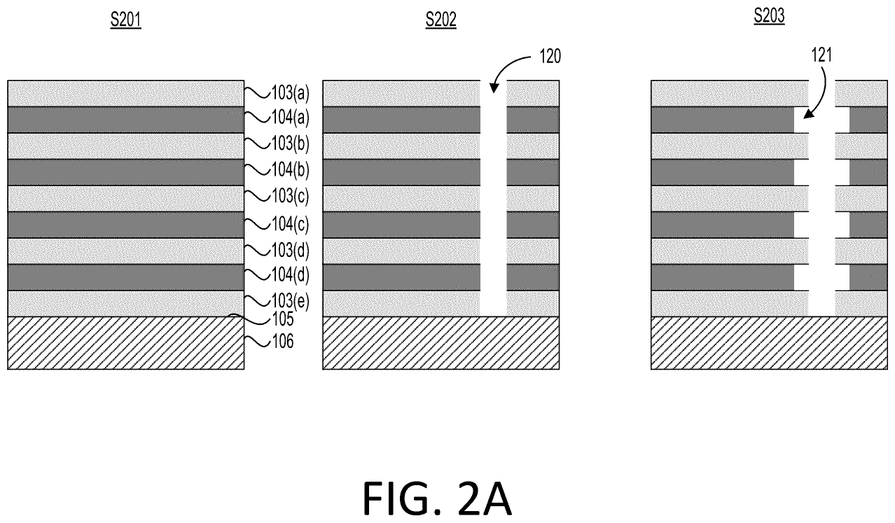

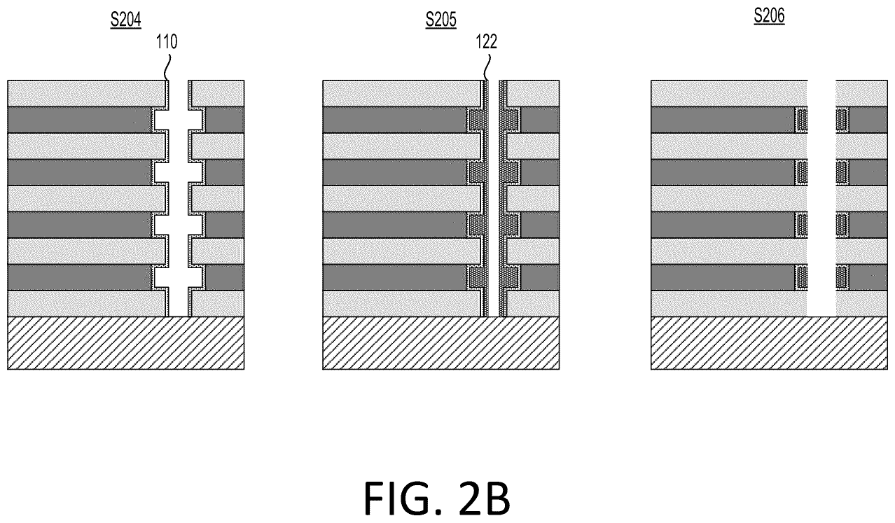

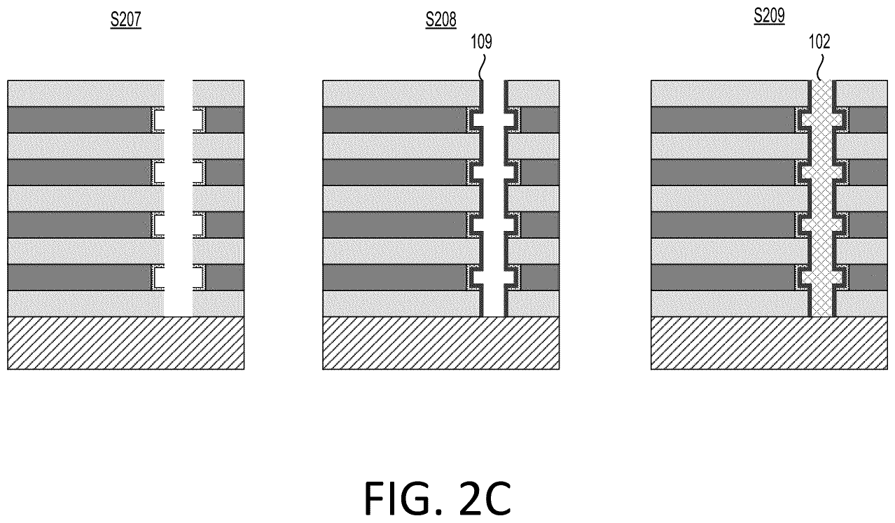

FIGS. 2A-2C illustrate a series of processing steps of manufacturing the semiconductor device 100 according to an embodiment of the disclosure. The semiconductor device 100 may be included in a microprocessor, memory cell, and/or other integrated circuit device. FIGS. 2A-2C have been simplified for the sake of clarity to better understand the concepts of the present disclosure. Additional features can be added in the semiconductor device 100, and some of the features described below can be replaced or eliminated in other embodiments of the semiconductor device 100.

Specifically, at step S201, the stack of alternating first layers 103 and second layers 104 can be formed on the working surface 105 of the substrate 106 of the semiconductor device 100.

At step S202, a hole structure 120 can be formed through the stack of alternating first layers 103 and second layers 104. In an example, the hole structure 120 can be formed using an anisotropic etching process. Sidewalls of the hole structure 120 can be perpendicular to the working surface 105 of the substrate 106.

At step S203, a plurality of recesses 121 can be formed in the second layers 104 through the hole structure 120. In an example, the plurality of recesses 121 can be formed using an isotropic etching process. Sidewalls of the recesses 121 can be parallel to the working surface 105 of the substrate 106. Bottom surfaces of the recesses 121 can be perpendicular to the working surface 105 of the substrate 106.

At step S204, the second electrode layer 110 can be formed over the sidewalls of the hole structure 120 and the sidewalls and bottom surfaces of the plurality of recesses 121. In an example, the second electrode layer 110 can be formed using an atomic layer deposition (ALD) process.

At step S205, a sacrificial layer 122 can be formed over the second electrode layer 110 on the sidewalls of the hole structure 120 and the sidewalls and bottom surfaces of the plurality of recesses 121, so that the recesses 121 can be fully filled with the sacrificial layer 122. In an example, the sacrificial layer 122 can be formed using the ALD process.

At step S206, the sacrificial layer 122 formed over the second electrode layer 110 on the sidewalls of the hole structure 120 can be removed, and the second electrode layer 110 on the sidewalls of the hole structure 120 can be also removed, so that the first layers 103 can be exposed. In an example, the sacrificial layer 122 formed over the second electrode layer 110 on the sidewalls of the hole structure 120 and the second electrode layer 110 on the sidewalls of the hole structure 120 can be removed using the isotropic etching process. It is noted that a portion of the sacrificial layer 122 filled in the recesses 121 can still be remained after step S206.

At step S207, the remained portion of the sacrificial layer 122 filled in the recesses 121 can be removed so that the second electrode layer 110 in the recesses 121 can be exposed.

At step S208, the dielectric layer 109 can be formed over the sidewalls of the hole structure 120 and over the second electrode layer 110 in the recesses 121. In an example, the dielectric layer 109 can be formed using the ALD process.

At step S209, the hole structure 120 can be fully filled with a conductive material to form the common electrode 102.

In an embodiment, if the second layers 104 are formed of sacrificial layers, the sacrificial layers can be replaced with conducting layers in a further step if needed.

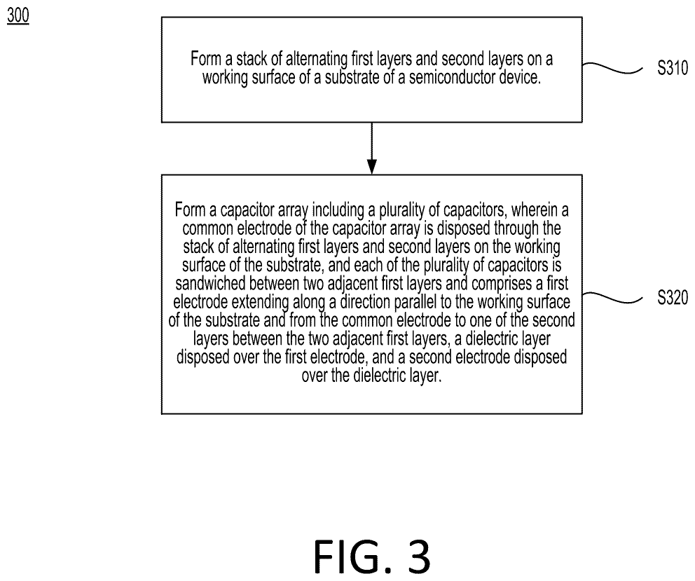

FIG. 3 illustrates a flowchart outlining a semiconductor process 300 for manufacturing a semiconductor device (e.g., the semiconductor device 100) according to an embodiment of the disclosure. The semiconductor process 300 can be implemented by a wafer processing system. The semiconductor process 300 can be implemented as instructions stored in a non-transitory computer-readable medium. When executed by for example the wafer processing system, the instructions can cause the wafer processing system to perform the semiconductor process 300. The semiconductor process 300 may start at step S310.

At step S310, the process 300 forms a stack of alternating first layers (e.g., the first layers 103) and second layers (e.g., the second layers 104) on a working surface (e.g., the working surface 105) of a substrate (e.g., the substrate 106) of the semiconductor device (e.g., the semiconductor device 100). Then, the process 300 can proceed to steps S320.

At step S320, the process 300 forms a capacitor array (e.g., the capacitor array 101) including a plurality of capacitors (e.g., the plurality of capacitors 107). A common electrode (e.g., the common electrode 102) of the capacitor array is disposed through the stack of alternating first layers and second layers on the working surface of the substrate. Each of the plurality of capacitors (e.g., the capacitor 107(a)) is sandwiched between two adjacent first layers (e.g., the two adjacent first layers 103(a) and 103(b)) and includes a first electrode (e.g., the first electrode 108(a)) extending along a direction parallel to the working surface of the substrate and from the common electrode to one of the second layers (e.g., the second layer 104(a)) between the two adjacent first layers, a dielectric layer (e.g., the dielectric layer 109(a)) disposed over the first electrode, and a second electrode (e.g., the second electrode 110(a)) disposed over the dielectric layer.

In an embodiment, the first layers are insulating layers.

In an embodiment, the second layers are conducting layers or sacrificial layers.

In an embodiment, the first electrodes of the plurality of capacitors and the common electrode of the capacitor array are formed of a same conducting material.

In an embodiment, the dielectric layers of two adjacent capacitors are connected to each other through a dielectric layer (e.g., the dielectric layer 109(c)) surrounding a portion of the common electrode.

In an embodiment, the portion of the common electrode is between two adjacent second layers (e.g., the two adjacent second layers 104(a) and 104(b)).

In an embodiment, the dielectric layer surrounding the portion of the common electrode is between the portion of the common electrode and one of the first layers (e.g., the first layer 103(b)).

In an embodiment, the first electrode of each of the plurality of capacitors has first and second surfaces parallel to the working surface of the substrate and a third surface perpendicular to the working surface of the substrate.

In an embodiment, the dielectric layer of each of the plurality of capacitors has three portions. First and second portions of the dielectric layer respectively are disposed over the first and second surfaces of the first electrode of the respective capacitor, and a third portion of the dielectric layer is disposed over the third surface of the first electrode of the respective capacitor.

In an embodiment, the second electrode of each of the plurality of capacitors has three portions. A first portion of the second electrode is disposed between the first portion of the dielectric layer of the respective capacitor and one of the two adjacent first layers immediately above the one of the second layers. A second portion of the second electrode is disposed between the second portion of the dielectric layer of the respective capacitor and the other of the two adjacent first layers immediately below the one of the second layers. A third portion of the second electrode is disposed between the third portion of the dielectric layer of the respective capacitor and the one of the second layers.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A semiconductor device, comprising:
a substrate;
a stack of alternating first layers and second layers on a working surface of the substrate; and
a capacitor array including a plurality of capacitors, wherein a common electrode of the capacitor array is disposed through the stack of alternating first layers and second layers on the working surface of the substrate, and each of the plurality of capacitors is sandwiched between two adjacent first layers and comprises
a first electrode extending along a direction parallel to the working surface of the substrate and from the common electrode to one of the second layers between the two adjacent first layers,
a dielectric layer disposed over the first electrode, and
a second electrode disposed over the dielectric layer.

2. The semiconductor device of claim 1, wherein the first layers are insulating layers.

3. The semiconductor device of claim 1, wherein the second layers are conducting layers or sacrificial layers.

4. The semiconductor device of claim 1, wherein the first electrodes of the plurality of capacitors and the common electrode of the capacitor array are formed of a same conducting material.

5. The semiconductor device of claim 1, wherein the dielectric layers of two adjacent capacitors are connected to each other through a dielectric layer surrounding a portion of the common electrode.

6. The semiconductor device of claim 5, wherein the portion of the common electrode is between two adjacent second layers.

7. The semiconductor device of claim 5, wherein the dielectric layer surrounding the portion of the common electrode is between the portion of the common electrode and one of the first layers.

8. The semiconductor device of claim 1, wherein the first electrode of each of the plurality of capacitors has first and second surfaces parallel to the working surface of the substrate and a third surface perpendicular to the working surface of the substrate.

9. The semiconductor device of claim 8, wherein the dielectric layer of each of the plurality of capacitors has three portions, first and second portions of the dielectric layer respectively being disposed over the first and second surfaces of the first electrode of the respective capacitor, and a third portion of the dielectric layer being disposed over the third surface of the first electrode of the respective capacitor.

10. The semiconductor device of claim 9, wherein the second electrode of each of the plurality of capacitors has three portions, a first portion of the second electrode being disposed between the first portion of the dielectric layer of the respective capacitor and one of the two adjacent first layers immediately above the one of the second layers, a second portion of the second electrode being disposed between the second portion of the dielectric layer of the respective capacitor and the other of the two adjacent first layers immediately below the one of the second layers, and a third portion of the second electrode being disposed between the third portion of the dielectric layer of the respective capacitor and the one of the second layers.

11. A method of manufacturing a semiconductor device, the method comprising:
forming a stack of alternating first layers and second layers on a working surface of a substrate of the semiconductor device; and
forming a capacitor array including a plurality of capacitors, wherein a common electrode of the capacitor array is disposed through the stack of alternating first layers and second layers on the working surface of the substrate, and each of the plurality of capacitors is sandwiched between two adjacent first layers and comprises
a first electrode extending along a direction parallel to the working surface of the substrate and from the common electrode to one of the second layers between the two adjacent first layers,
a dielectric layer disposed over the first electrode, and
a second electrode disposed over the dielectric layer.

12. The method of claim 11, wherein the first layers are insulating layers.

13. The method of claim 11, wherein the second layers are conducting layers or sacrificial layers.

14. The method of claim 11, wherein the first electrodes of the plurality of capacitors and the common electrode of the capacitor array are formed of a same conducting material.

15. The method of claim 11, wherein the dielectric layers of two adjacent capacitors are connected to each other through a dielectric layer surrounding a portion of the common electrode.

16. The method of claim 15, wherein the portion of the common electrode is between two adjacent second layers.

17. The method of claim 15, wherein the dielectric layer surrounding the portion of the common electrode is between the portion of the common electrode and one of the first layers.

18. The method of claim 11, wherein the first electrode of each of the plurality of capacitors has first and second surfaces parallel to the working surface of the substrate and a third surface perpendicular to the working surface of the substrate.

19. The method of claim 18, wherein the dielectric layer of each of the plurality of capacitors has three portions, first and second portions of the dielectric layer respectively being disposed over the first and second surfaces of the first electrode of the respective capacitor, and a third portion of the dielectric layer being disposed over the third surface of the first electrode of the respective capacitor.

20. The method of claim 19, wherein the second electrode of each of the plurality of capacitors has three portions, a first portion of the second electrode being disposed between the first portion of the dielectric layer of the respective capacitor and one of the two adjacent first layers immediately above the one of the second layers, a second portion of the second electrode being disposed between the second portion of the dielectric layer of the respective capacitor and the other of the two adjacent first layers immediately below the one of the second layers, and a third portion of the second electrode being disposed between the third portion of the dielectric layer of the respective capacitor and the one of the second layers.
